(19) United States
(12) Patent Application Publication
(10) Pub. No.: US 2025/0372171 A1
(43) Pub. Date: Dec. 4, 2025

(54) DRIVING CIRCUIT, MEMORY DEVICE USING DRIVING CIRCUIT, AND MEMORY SYSTEM

(71) Applicant: YANGTZE MEMORY TECHNOLOGIES CO., LTD., Wuhan (CN)

(72) Inventors: Mingxian Lei, Wuhan (CN); Ruxin Wei, Wuhan (CN)

(21) Appl. No.: 18/750,892

(22) Filed: Jun. 21, 2024

Related U.S. Application Data
(63) Continuation of application No. PCT/CN2024/096351, filed on May 30, 2024.

(51) Int. Cl. G11C 16/08; G11C 16/04

(52) U.S. Cl. CPC G11C 16/08; G11C 16/0483

(57) ABSTRACT

A driving circuit includes a first-stage amplifier circuit having a first input end receiving an input signal, a second input end receiving a feedback signal, and a first output end providing a driving signal, and a second-stage amplifier circuit having a third input end connecting the first output end to receive the driving signal, a second output end providing an output signal, and a third output end providing the feedback signal. The first-stage amplifier circuit includes a first voltage source having a first voltage level. The second-stage amplifier circuit includes a pull-up subcircuit having a fourth input end and a fourth output end, and a pull-down subcircuit having a fifth input end and a fifth output end. The fourth input end and the fifth input end connect to the third input end, and the fourth output end and the fifth output end connect to the second output end.

### CROSS-REFERENCE TO RELATED APPLICATIONS

This application is a continuation of International Application No. PCT/CN2024/096351, filed on May 30, 2024, which is hereby incorporated by reference in its entirety.

### BACKGROUND

The present disclosure relates to the driving circuits, and specifically, relates to the memory devices using the driving circuits and the memory system.

Planar memory cells are scaled to smaller sizes by improving process technology, circuit design, programming algorithm, and fabrication process. However, as feature sizes of the memory cells approach a lower limit, planar process and fabrication techniques become challenging and costly. As a result, memory density for planar memory cells approaches an upper limit.

A 3D memory architecture can address the density limitation in planar memory cells. The 3D memory architecture includes a memory array and peripheral circuits for facilitating operations of the memory array.

### SUMMARY

According to one aspect of the present disclosure, a driving circuit is disclosed. The driving circuit includes a first-stage amplifier circuit having a first input end receiving an input signal, a second input end receiving a feedback signal, and a first output end providing a driving signal, and a second-stage amplifier circuit having a third input end connecting the first output end to receive the driving signal, a second output end providing an output signal, and a third output end providing the feedback signal. The first-stage amplifier circuit includes a first voltage source having a first voltage level. The second-stage amplifier circuit includes a pull-up subcircuit having a fourth input end and a fourth output end, and a pull-down subcircuit having a fifth input end and a fifth output end. The fourth input end and the fifth input end connect to the third input end, and the fourth output end and the fifth output end connect to the second output end.

In some implementations, the second-stage amplifier circuit further includes a second voltage source having a second voltage level different from the first voltage level, and a third voltage source having a third voltage level different from the first voltage level and the second voltage level.

In some implementations, the pull-up subcircuit pulls up an output voltage level of the output signal when a first input voltage level of the input signal is higher than a feedback voltage level of the feedback signal, and the pull-down subcircuit pulls down the output voltage level of the output signal when the first input voltage level of the input signal is lower than the feedback voltage level of the feedback signal.

In some implementations, the first-stage amplifier circuit and the second-stage amplifier circuit further include a ground reference voltage source.

In some implementations, the first-stage amplifier circuit includes a differential amplifier comparing the input signal and the feedback signal and generating the driving signal according to a comparison result of the differential amplifier.

In some implementations, the second-stage amplifier circuit pulls up or pulls down the output voltage level of the output signal according to the comparison result of the differential amplifier.

In some implementations, the second voltage level of the second voltage source is greater than the third voltage level of the third voltage source.

In some implementations, the second voltage level is between 13 volts and 17 volts.

In some implementations, the third voltage level is between 10 volts and 14 volts.

In some implementations, the pull-up subcircuit includes a first transistor having a first end receiving the driving signal, a second end connecting the ground reference voltage source, and a third end, a second transistor having a fourth end connecting the third end of the first transistor, a fifth end connecting the third end of the first transistor, and a sixth end connecting the second voltage source, and a third transistor having a seventh end connecting the fourth end of the second transistor, an eighth end connecting the output end, and a ninth end connecting the third voltage source.

In some implementations, the pull-up subcircuit further includes a first high-voltage transistor disposed between the first transistor and the second transistor.

In some implementations, the pull-up subcircuit further includes a first current source disposed between the first high-voltage transistor and the second transistor.

In some implementations, the third transistor is disposed between the third voltage source and the output end.

In some implementations, the pull-down subcircuit includes a fourth transistor having a tenth end connecting the third end of the first transistor, an eleventh end connecting the ground reference voltage source, and a twelfth end connecting the second voltage source, and a fifth transistor having a thirteenth end connecting the second voltage source, a fourteenth end connecting the ground reference voltage source, and a fifteenth end connecting the output end.

In some implementations, the pull-down subcircuit further includes a second high-voltage transistor disposed between the fourth transistor and the second voltage source.

According to another aspect of the present disclosure, a memory device is disclosed. The memory device includes a memory cell array having a plurality of memory cells and a plurality of word lines coupled to the plurality of memory cells, and a peripheral circuit, coupled to the memory cell array, configured to control the memory cell array. The peripheral circuit includes a driving circuit. The driving circuit includes a first-stage amplifier circuit having a first input end receiving an input signal, a second input end receiving a feedback signal, and a first output end providing a driving signal, and a second-stage amplifier circuit having a third input end connecting the first output end to receive the driving signal, a second output end providing an output signal, and a third output end providing the feedback signal. The first-stage amplifier circuit includes a first voltage source having a first voltage level. The second-stage amplifier circuit includes a pull-up subcircuit having a fourth input end and a fourth output end, and a pull-down subcircuit having a fifth input end and a fifth output end. The fourth input end and the fifth input end connect to the third input end, and the fourth output end and the fifth output end connect to the second output end.

In some implementations, the second-stage amplifier circuit further includes a second voltage source having a second voltage level different from the first voltage level, and a third voltage source having a third voltage level different from the first voltage level and the second voltage level.

In some implementations, the pull-up subcircuit pulls up an output voltage level of the output signal when a first input voltage level of the input signal is higher than a feedback voltage level of the feedback signal, and the pull-down subcircuit pulls down the output voltage level of the output signal when the first input voltage level of the input signal is lower than the feedback voltage level of the feedback signal.

In some implementations, the peripheral circuit includes a voltage generator and a word line driver, and the voltage generator provides the second voltage source and the output signal to the word line driver.

In some implementations, the first-stage amplifier circuit and the second-stage amplifier circuit further include a ground reference voltage source.

In some implementations, the pull-up subcircuit includes a first transistor having a first end receiving the driving signal, a second end connecting the ground reference voltage source, and a third end, a second transistor having a fourth end connecting the third end of the first transistor, a fifth end connecting the third end of the first transistor, and a sixth end connecting the second voltage source, and a third transistor having a seventh end connecting the fourth end of the second transistor, an eighth end connecting the output end, and a ninth end connecting the third voltage source.

In some implementations, the pull-up subcircuit further includes a first high-voltage transistor disposed between the first transistor and the second transistor, and a first current source disposed between the first high-voltage transistor and the second transistor.

In some implementations, the pull-down subcircuit includes a fourth transistor having a tenth end connecting the third end of the first transistor, an eleventh end connecting the ground reference voltage source, a twelfth end connecting the second voltage source, and a fifth transistor having a thirteenth end connecting the second voltage source, a fourteenth end connecting the ground reference voltage source, and a fifteenth end connecting the output end.

In some implementations, the pull-down subcircuit further includes a second high-voltage transistor disposed between the fourth transistor and the second voltage source.

According to a further aspect of the present disclosure, a system is disclosed. The system includes a memory device and a memory controller coupled to the memory device and configured to control the operations of a peripheral circuit. The memory device includes a memory cell array having a plurality of memory cells and a plurality of word lines coupled to the plurality of memory cells, and a peripheral circuit, coupled to the memory cell array, configured to control the memory cell array. The peripheral circuit includes a driving circuit. The driving circuit includes a first-stage amplifier circuit having a first input end receiving an input signal, a second input end receiving a feedback signal, and a first output end providing a driving signal, and a second-stage amplifier circuit having a third input end connecting the first output end to receive the driving signal, a second output end providing an output signal, and a third output end providing the feedback signal. The first-stage amplifier circuit includes a first voltage source having a first voltage level. The second-stage amplifier circuit includes a pull-up subcircuit having a fourth input end and a fourth output end, and a pull-down subcircuit having a fifth input end and a fifth output end. The fourth input end and the fifth input end connect to the third input end, and the fourth output end and the fifth output end connect to the second output end.

### BRIEF DESCRIPTION OF THE DRAWINGS

In order to illustrate the technical solutions in the present disclosure more clearly, the accompanying drawings required in some implementations of the present disclosure will be briefly introduced in the following. Obviously, the accompanying drawings in the following description are only figures of some implementations of the present disclosure. For those of ordinary skill in the art, other drawings can also be obtained based on these drawings. In addition, the drawings in the following description can be regarded as schematic diagrams, and are not limitations on the actual size of the product involved in the implementations of the present disclosure, the actual process of the method, the actual timing of signals, and the like.

FIG. 1A illustrates a schematic view of a cross-section of an exemplary memory device, according to some implementations of the present disclosure.

FIG. 1B illustrates a schematic view of a cross-section of another exemplary memory device, according to some implementations of the present disclosure.

FIG. 2 illustrates a schematic diagram of an exemplary memory device including peripheral circuits, according to some implementations of the present disclosure.

FIG. 3 illustrates a block diagram of an exemplary memory device including a memory cell array and peripheral circuits, according to some implementations of the present disclosure.

FIG. 4 illustrates a schematic structural diagram of an exemplary memory cell block, according to some implementations of the present disclosure.

FIG. 5 illustrates a schematic diagram of an exemplary memory cell block, according to some implementations of the present disclosure.

FIG. 6 illustrates a schematic diagram of voltage application to word lines and select lines for performing read operations on memory cells, according to some implementations of the present disclosure.

FIG. 7 illustrates a block diagram of an exemplary driving circuit, according to some implementations of the present disclosure.

FIG. 8 illustrates a schematic diagram of an exemplary driving circuit, according to some implementations of the present disclosure.

FIG. 9 illustrates a schematic diagram of an exemplary driving circuit, according to some implementations of the present disclosure.

FIG. 10 illustrates a timing diagram showing the operation of an exemplary driving circuit, according to some implementations of the present disclosure.

FIG. 11 illustrates a block diagram of an exemplary system having a memory device, according to some implementations of the present disclosure.

FIG. 12A illustrates a diagram of an exemplary memory card having a memory device, according to some implementations of the present disclosure.

FIG. 12B illustrates a diagram of an exemplary solid-state drive (SSD) having a memory device, according to some implementations of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features, as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical interconnect access (via) contacts are formed) and one or more dielectric layers.

Flash memory is a non-volatile memory that can be electrically erased and reprogrammed, which may include memories with two architectures: NOR and NAND. The present disclosure takes NAND flash memory as an example for further explanation. A three-dimensional (3D) NAND flash memory cell array may include multiple memory cell blocks and multiple layers of word lines. In the program and read operation, only one word line is selected, and the other word lines are unselected. The bias voltage required for the cells of the erase pattern only needs about 1 volt, and the unselected word lines are reset to VDD (about 2 volts) when starting up. Hence, a relatively strong pull-down capability is required when programming. In the conventional implementations, an indicator signal was required to select the pull-up and pull-down paths, and the driving circuit occupies a large area of the device.

To address one or more of the aforementioned issues, the present disclosure introduces a solution in which the indicator signal for selecting the pull-up and pull-down paths is not required. Therefore, the circuit area and the elements in the memory device can be effectively reduced. In addition, two voltage sources are provided to the second-stage amplifier circuit for driving the pull-up and pull-down circuits, and the two voltage sources are provided by the original existing voltage sources in the voltage generator therefore no extra circuit is needed.

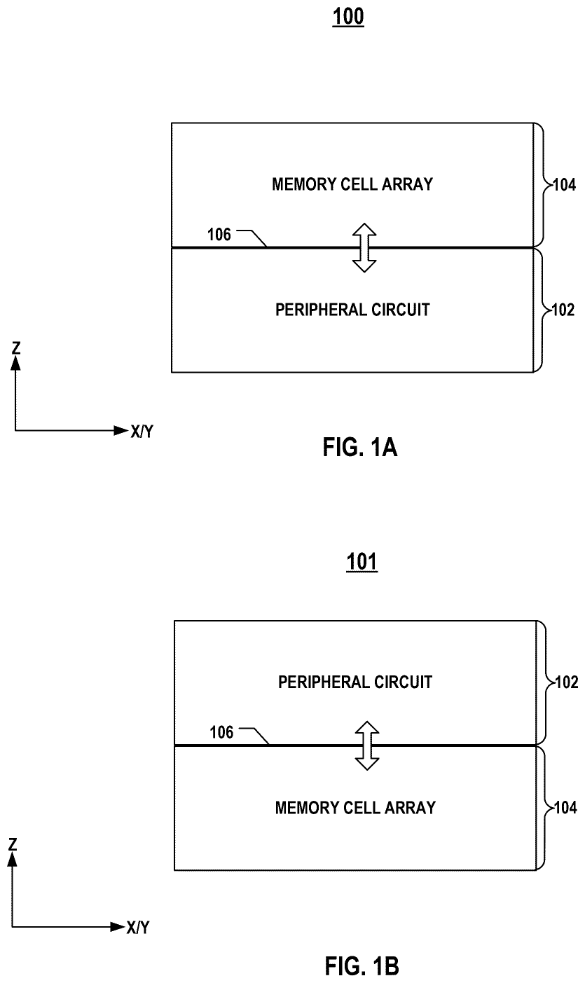

FIG. 1A illustrates a schematic view of a cross-section of a memory device 100, according to some aspects of the present disclosure. The memory device 100 represents an example of a bonded chip. The components of memory device 100 (e.g., memory cell array and peripheral circuits) can be formed separately on different substrates and then jointly form a bonded chip. Memory device 100 can include a first semiconductor structure 102 including the peripheral circuits of a memory cell array. Memory device 100 can also include a second semiconductor structure 104 including the memory cell array. The peripheral circuits (e.g., control and sensing circuits) can include any suitable digital, analog, and/or mixed-signal circuits used for facilitating the operations of the memory cell array. For example, the peripheral circuit can include one or more of a page buffer, a decoder (e.g., a row decoder and a column decoder), a sense amplifier, a driver (e.g., a word line driver), an input/output (I/O) circuit, a charge pump, a voltage source or generator, a current or voltage reference, any portions (e.g., a sub-circuit) of the functional circuits mentioned above, or any active or passive components of the circuit (e.g., transistors, diodes, resistors, or capacitors). The peripheral circuits in the first semiconductor structure 102 use complementary metal-oxide-semiconductor (CMOS) technology, e.g., which can be implemented with logic processes (e.g., technology nodes of 90 nm, 65 nm, 60 nm, 45 nm, 32 nm, 28 nm, 22 nm, 20 nm, 16 nm, 14 nm, 10 nm, 7 nm, 5 nm, 3 nm, 2 nm, etc.), according to some implementations.

As shown in FIG. 1A, memory device 100 can also include the second semiconductor structure 104 including an array of memory cells (memory cell array) that can use transistors as the switch and selecting devices. It is understood that the memory cell array is not limited to any specific kind of memory cell array and may include any other suitable types of memory cell arrays that can use transistors as the switch and selecting devices, such as dynamic random-access memory (DRAM) cell array, phase-change memory (PCM) cell array, static random-access memory (SRAM) cell array, ferroelectric DRAM (FRAM) cell array, resistive memory cell array, magnetic memory cell array, spin transfer torque (STT) memory cell array, to name a few, or any combination thereof.

As shown in FIG. 1A, memory device 100 further includes a bonding interface 106 vertically between (in the vertical direction, e.g., the Z-direction in FIG. 1A) the first semiconductor structure 102 and the second semiconductor structure 104. As described below in detail, the first and second semiconductor structures 102 and 104 can be fabricated separately (and in parallel in some implementations) such that the thermal budget of fabricating one of the first and second semiconductor structures 102 and 104 does not limit the processes of fabricating another one of the first and second semiconductor structures 102 and 104. Moreover, a large number of interconnects (e.g., bonding contacts) can be formed through bonding interface 106 to make direct, short-distance (e.g., micron-level) electrical connections between the first semiconductor structure 102 and second semiconductor structure 104, as opposed to the long-distance (e.g., millimeter or centimeter-level) chip-to-chip data bus on the circuit board, such as printed circuit board (PCB), thereby eliminating chip interface delay and achieving high-speed I/O throughput with reduced power consumption. Data transfer between the memory cell array in the second semiconductor structure 104 and the peripheral circuits in the first semiconductor structure 102 can be performed through the interconnects (e.g., bonding contacts) across the bonding interface 106. By vertically integrating the first and second semiconductor structures 102 and 104, the chip size can be reduced, and the memory cell density can be increased.

It is understood that the relative positions of the stacked first and second semiconductor structures 102 and 104 are not limited. FIG. 1B illustrates a schematic view of a cross-section of another exemplary memory device 101, according to some implementations. Different from memory device 100 in FIG. 1A, in which the second semiconductor structure 104 including the memory cell array is above the first semiconductor structure 102 including the peripheral circuits, in memory device 101 in FIG. 1B, the first semiconductor structure 102 including the peripheral circuit is above the second semiconductor structure 104 including the memory cell array. Nevertheless, the bonding interface 106 is formed vertically between the first and second semiconductor structures 102 and 104 in the memory device 101, and the first and second semiconductor structures 102 and 104 are jointed vertically through bonding (e.g., hybrid bonding) according to some implementations. Hybrid bonding, also known as “metal/dielectric hybrid bonding,” is a direct bonding technology (e.g., forming bonding between surfaces without using intermediate layers, such as solder or adhesives) and can obtain metal-metal (e.g., copper-to-copper) bonding and dielectric-dielectric (e.g., silicon oxide-to-silicon oxide) bonding simultaneously. Data transfer between the memory cell array in the second semiconductor structure 104 and the peripheral circuits in the first semiconductor structure 102 can be performed through the interconnects (e.g., bonding contacts) across the bonding interface 106.

It is noted that the X, Y, and Z axes are included in FIGS. 1A and 1B to further illustrate the spatial relationship of the components in memory devices 100 and 101. The substrate of the memory device includes two lateral surfaces extending laterally in the X-Y plane: a top surface on the front side of the wafer on which the semiconductor devices can be formed, and a bottom surface on the backside opposite to the front side of the wafer. The Z-axis is perpendicular to both the X and Y axes. As used herein, whether one component (e.g., a layer or a device) is “on,” “above,” or “below” another component (e.g., a layer or a device) of the memory device is determined relative to the substrate of the memory device in the Z-direction (the vertical direction perpendicular to the X-Y plane, e.g., the thickness direction of the substrate) when the substrate is positioned in the lowest plane of the memory device in the Z-direction. The same notion for describing the spatial relationships is applied throughout the present disclosure.

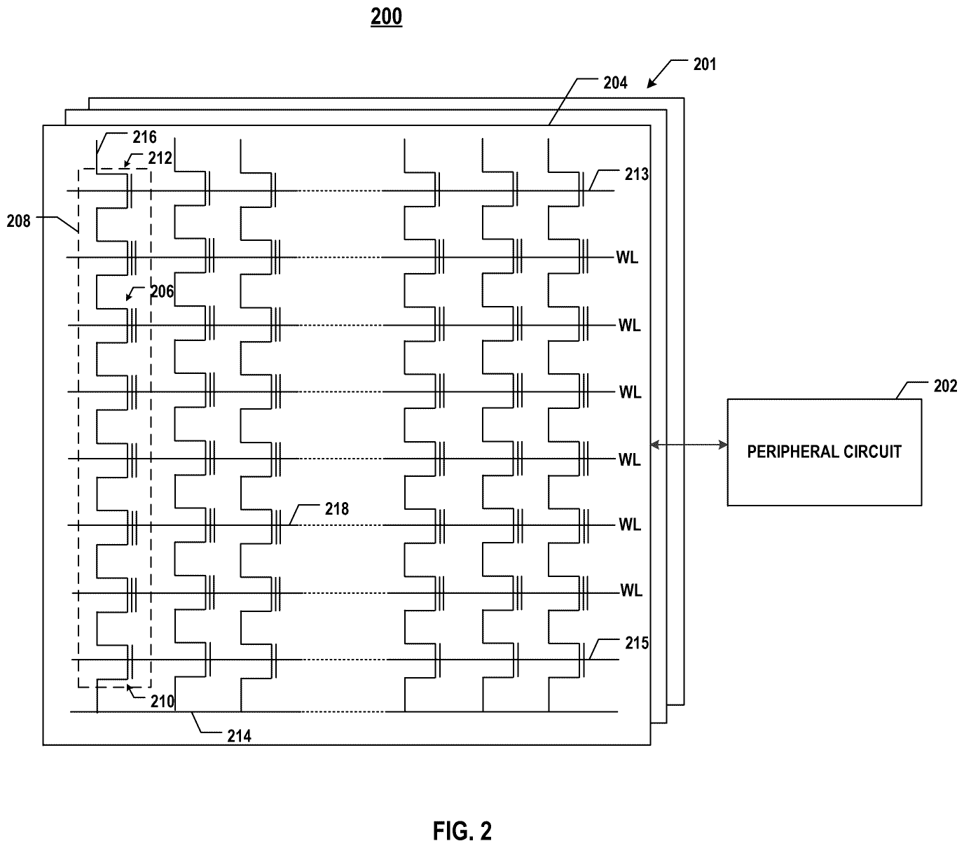

FIG. 2 illustrates a schematic circuit diagram of a memory device 200 including peripheral circuits, according to some aspects of the present disclosure. Memory device 200 can include a memory cell array 201 and peripheral circuits 202 coupled to the memory cell array 201. Memory cell array 201 can be a NAND Flash memory cell array in which memory cells 206 are provided in the form of an array of NAND memory strings 208 each extending vertically above a substrate (not shown in FIG. 2). In some implementations, each NAND memory string 208 includes a plurality of memory cells 206 coupled in series and stacked vertically. Each memory cell 206 can hold a continuous, analog value, such as an electrical voltage or charge, that depends on the number of electrons trapped within a region of memory cell 206. Each memory cell 206 can be either a floating gate type of memory cell including a floating-gate transistor or a charge trap type of memory cell including a charge-trap transistor.

In some implementations, each memory cell 206 is a single-level cell (SLC) that has two possible memory states and thus, can store one bit of data. For example, the first memory state “0” can correspond to a first range of voltages, and the second memory state “1” can correspond to a second range of voltages. In some implementations, each memory cell 206 is a multi-level cell (MLC) that is capable of storing more than a single bit of data in more than four memory states. For example, the MLC can store two bits per cell, three bits per cell (also known as triple-level cell (TLC)), or four bits per cell (also known as a quad-level cell (QLC)). Each MLC can be programmed to assume a range of possible nominal storage values. In one example, if each MLC stores two bits of data, then the MLC can be programmed to assume one of three possible programming levels from an erased state by writing one of three possible nominal storage values to the cell. A fourth nominal storage value can be used for the erased state.

As shown in FIG. 2, each NAND memory string 208 can include a source select gate (SSG) transistor 210 at its source end and a drain select gate (DSG) transistor 212 at its drain end. SSG transistor 210 and DSG transistor 212 can be configured to activate selected NAND memory strings 208 (columns of the array) during read and program operations. In some implementations, SSG transistors 210 of NAND memory strings 208 in the same block 204 are coupled through a same source line (SL) 214, e.g., a common SL, for example, to the ground. DSG transistor 212 of each NAND memory string 208 is coupled to a respective bit line 216 from which data can be read or programmed via an output bus (not shown), according to some implementations. In some implementations, each NAND memory string 208 is configured to be selected or deselected by applying a select voltage (e.g., above the threshold voltage of DSG transistor 212) or a deselect voltage (e.g., 0 V) to respective DSG transistor 212 through one or more DSG lines 213 and/or by applying a select voltage (e.g., above the threshold voltage of SSG transistor 210) or a deselect voltage (e.g., 0 V) to respective SSG transistor 210 through one or more SSG lines 215.

As shown in FIG. 2, NAND memory strings 208 can be organized into multiple blocks 204, each of which can have a common source line 214. In some implementations, each block 204 is the basic data unit for erase operations, e.g., all memory cells 206 on the same block 204 are erased at the same time. Memory cells 206 of adjacent NAND memory strings 208 can be coupled through word lines 218 that select which row of memory cells 206 is affected by read and program operations. In some implementations, each word line 218 is coupled to a plurality of memory cells 206, which is the basic data unit for program and read operations. Each word line 218 can include a plurality of control gates (gate electrodes) at each memory cell 206 and a gate line coupling the control gates.

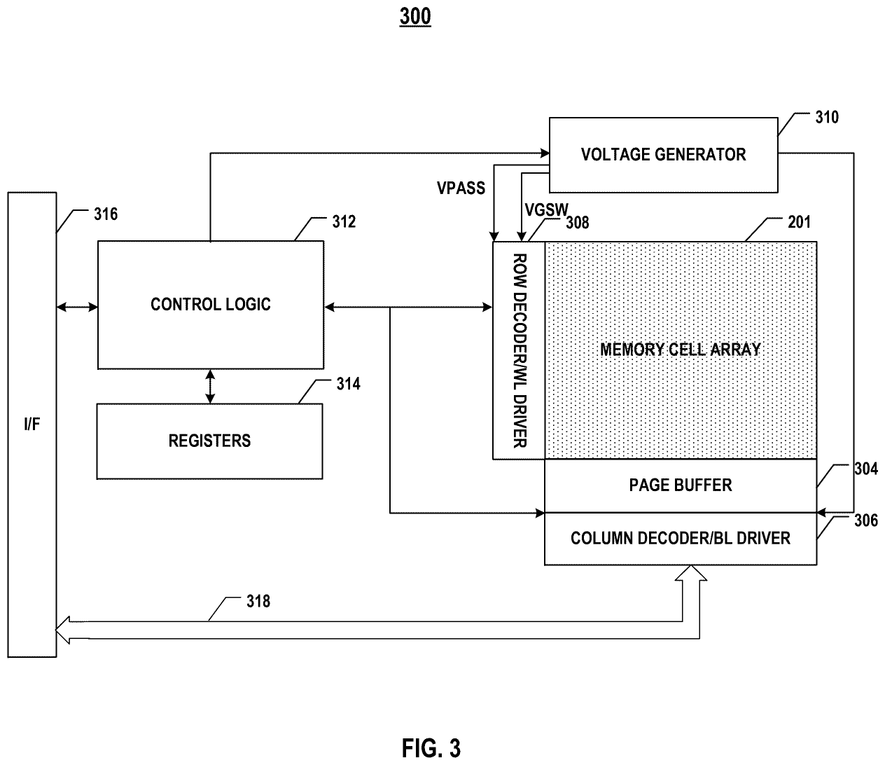

Peripheral circuits 202 can be coupled to memory cell array 201 through bit lines 216, word lines 218, source lines 214, SSG lines 215, and DSG lines 213. As described above, peripheral circuits 202 can include any suitable circuits for facilitating the operations of the memory cell array 201 by applying and sensing voltage signals and/or current signals through bit lines 216 to and from each target memory cell 206 through word lines 218, source lines 214, SSG lines 215, and DSG lines 213. Peripheral circuits 202 can include various types of peripheral circuits formed using CMOS technologies. For example, FIG. 3 illustrates some exemplary peripheral circuits 202 including a page buffer 304, a column decoder/bit line driver 306, a row decoder/word line driver 308, a voltage generator 310, control logic 312, registers 314, an interface (I/F) 316, and a data bus 318. It is understood that in some examples, additional peripheral circuits 202 may be included as well.

Page buffer 304 can be configured to buffer data read from or programmed to memory cell array 201 according to the control signals of control logic 312. In one example, page buffer 304 may store one page of program data (write data) to be programmed. In another example, page buffer 304 also performs program verify operations to ensure that the data has been properly programmed into memory cells 206 coupled to selected word lines 218.

Row decoder/word line driver 308 can be configured to be controlled by control logic 312 and select block 204 of memory cell array 201 and a word line 218 of selected block 204. Row decoder/word line driver 308 can be further configured to drive memory cell array 201. For example, row decoder/word line driver 308 may drive memory cells 206 coupled to the selected word line 218 using a word line voltage generated from voltage generator 310.

Column decoder/bit line driver 306 can be configured to be controlled by control logic 312 and select one or more 3D NAND memory strings 208 by applying bit line voltages generated from voltage generator 310. For example, column decoder/bit line driver 306 may apply column signals for selecting a set of N bits of data from page buffer 304 to be output in a read operation.

Control logic 312 can be coupled to each peripheral circuit 202 and configured to control operations of peripheral circuits 202. Registers 314 can be coupled to control logic 312 and include status registers, command registers, and address registers for storing status information, command operation codes (OP codes), and command addresses for controlling the operations of each peripheral circuit 202.

Interface 316 can be coupled to control logic 312 and configured to interface memory cell array 201 with a memory controller (not shown). In some implementations, interface 316 acts as a control buffer to buffer and relay control commands received from the memory controller and/or a host (not shown) to control logic 312 and status information received from control logic 312 to the memory controller and/or the host. Interface 316 can also be coupled to page buffer 304 and column decoder/bit line driver 306 via data bus 318 and act as an I/O interface and a data buffer to buffer and relay the program data received from the memory controller and/or the host to page buffer 304 and the read data from page buffer 304 to the memory controller and/or the host. In some implementations, interface 316 and data bus 318 are parts of an I/O circuit of peripheral circuits 202.

Voltage generator 310 can be configured to be controlled by control logic 312 and generate the word line voltages (e.g., read voltage, program voltage, pass voltage, local voltage, and verification voltage) and the bit line voltages to be supplied to memory cell array 201. In some implementations, voltage generator 310 is part of a voltage source that provides voltages at various levels of different peripheral circuits 202 as described below in detail. Consistent with the scope of the present disclosure, in some implementations, the voltages provided by voltage generator 310, for example, to row decoder/word line driver 308, column decoder/bit line driver 306, and page buffer 304 are above certain levels that are sufficient to perform the memory operations. For example, the voltages provided to the page buffer circuits in page buffer 304 and/or the logic circuits in control logic 312 may be between 1.3 V and 5 V, such as 3.3 V, and the voltages provided to the driving circuits in row decoder/word line driver 308 and/or column decoder/bit line driver 306 may be between 5 V and 30 V.

Voltage generator 310 can provide a data voltage (VDATA) to the first-stage amplifier circuit and provide the pass voltage (VPASS) and the gate switch voltage (VGSW) to the second-stage amplifier circuit for driving the pull-up and pull-down circuits.

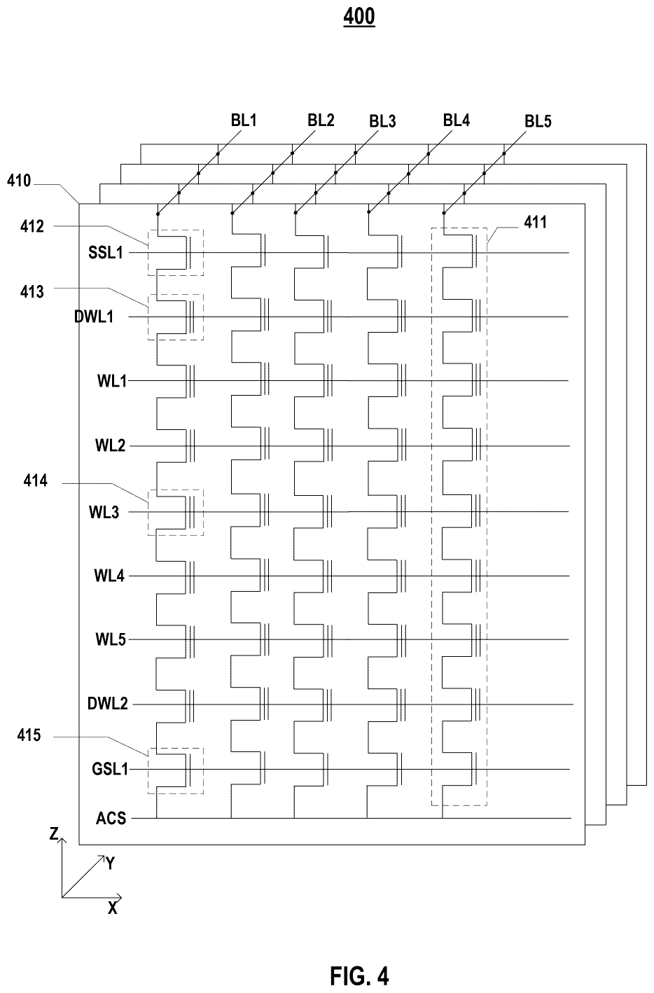

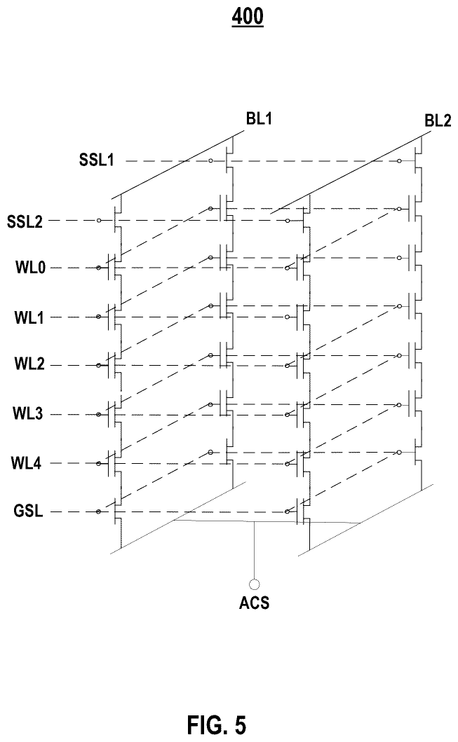

FIG. 4 and FIG. 5 illustrate schematic diagrams of an exemplary memory cell block 400, according to some aspects of the present disclosure. As shown in FIG. 4, the memory cell block 400 may include multiple memory cell strings 411, and N memory cell strings 411 are arranged along an X-axis into memory cell slices 410 (which may also be called “memory cell groups”). M memory cell slices 410 are arranged along a Y-axis into memory cell blocks 400. As an example, N=5 and M=4. Each memory cell string 411 may include a drain select gate (DSG) 412 (e.g., a top select gate (TSG)), a dummy memory cell 413, a plurality of memory cells 414, and a source select gate (SSG) 415 (e.g., a bottom select gate (BSG)) stacked in series along a Z-axis. The X-axis, Y-axis, and Z-axis are horizontal axis, longitudinal axis, and vertical axis of the space rectangular coordinate system, respectively. In some implementations, the memory cell in the NAND flash memory may be a field effect transistor capable of storing data, such as a floating gate transistor or a charge trap field effect transistor.

As shown in FIGS. 4 and 5, for M memory cell strings 411 in the same memory cell slice 410, the gate of the DSG 412 in each memory cell string 411 is coupled to the same string select line, and the gate of the SSG 415 in each memory cell string 411 is coupled to the same ground select line. The M memory cell strings 411 in the memory cell slice 410 are coupled to M bit lines (BL) in a one-to-one correspondence. For example, the drains of the DSGs 412 in the memory cell strings 411 are coupled to the bit lines. In order to reduce the number of bit lines, the memory cell strings 411 in N memory cell slices 410 can share M bit lines. In other words, the memory cell string 411 in any one memory cell slice 410 and memory cell strings 411 at corresponding positions in the other (N−1) memory cell slices 410 are coupled to the same bit line.

For the N*M memory cell strings 411 in the N memory cell slices 410, the control gate of the memory cell 414 in any one memory cell string 411 and the control gates of memory cells 414 at corresponding positions in other (N*M−1) memory cell strings 411 are coupled to the same word line. Furthermore, the control gate of the dummy memory cell 413 in any one memory cell string 411 and the control gates of the dummy memory cell 413 at corresponding positions in other (N*M−1) memory cell strings 411 are coupled to the same dummy word line (DWL). The memory cells 414 coupled to the same word line in a memory cell slice 410 may be called a memory cell page.

The sources of the SSGs 415 in the N*M memory cell strings 411 may be coupled to a common source line (CSL). The common source line may also be called an array common source (ACS). It should be noted that the drawings of the present disclosure only illustrate the structure of the memory in some implementations, and, in actual practice, the memory can be structured in other ways. For example, a source of an SSG 415 in the N*M memory cell strings 411 can be similar to the drain. The memory cell strings 411 in N memory cell slices 410 can share M source lines. That is, the memory cell strings 411 in any one memory cell slice 410 and the memory cell strings 411 at corresponding positions in other (N−1) memory cell slices 410 are coupled to the same source line.

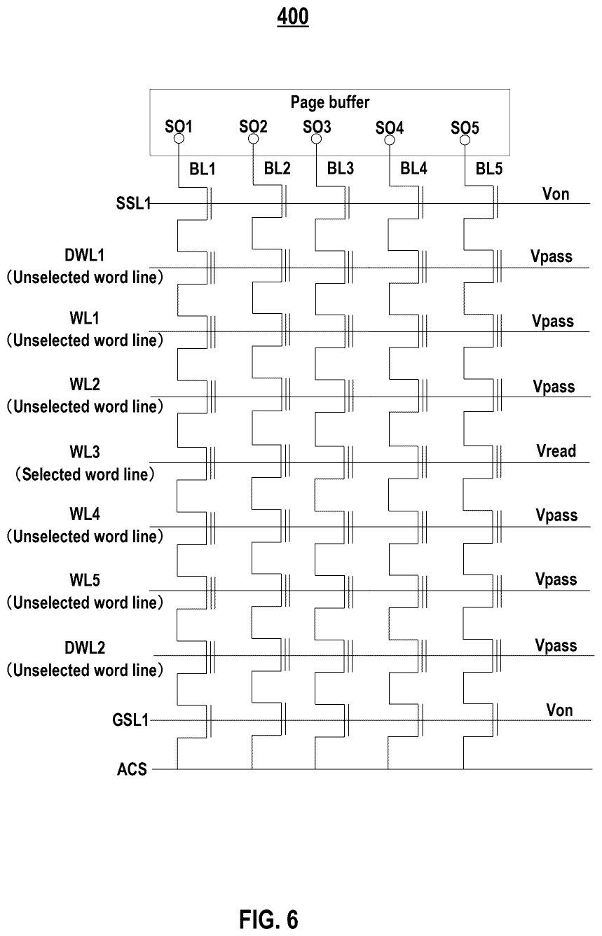

FIG. 6 illustrates a schematic diagram of voltage application to word lines and select lines for performing read operations on memory cells, according to some aspects of the present disclosure. Performing a read operation on the memory cell page is to measure the threshold voltage Vt of all memory cells 414 in the memory cell page. Because a direct measurement of the threshold voltage Vt of a memory cell can be challenging to obtain, and the output current of a memory cell is related to the gate voltage and threshold voltage Vt, the threshold voltage Vt of the memory cell may be determined by measuring the current.

As shown in FIG. 6, when performing a read operation, the bit line (BL) coupled to the memory cell string where the memory cell to be read is located, and the sensing node (SO) in the corresponding page buffer is first charged. Afterward, a turn-on voltage (Von) is applied to the selection line of the memory cell string where the memory cell to be read is located, a read voltage (Vread) is applied to the selected WL to which the memory cell to be read is coupled, and a pass voltage (Vpass) is applied to the unselected WLs other than the selected WL.

In some implementations, while the pass voltage (Vpass) is required for the unselected WLs, a circuit is configured to adaptively pull up and pull down the voltage provided to the unselected WLs.

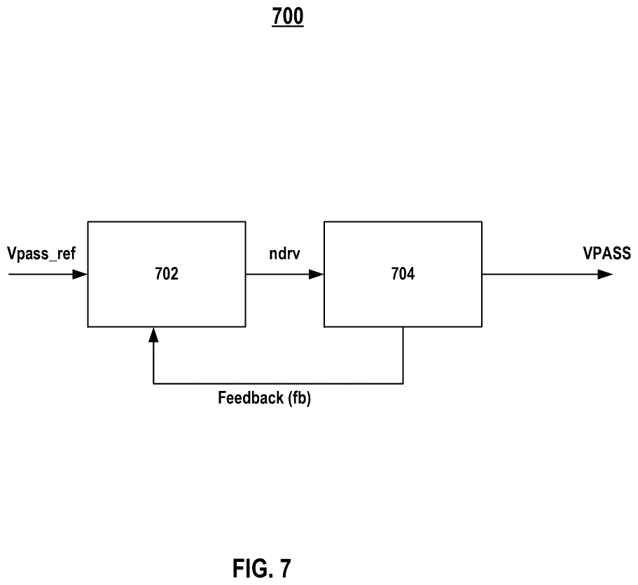

FIG. 7 illustrates a block diagram of a driving circuit 700, according to some implementations of the present disclosure. In some implementations, the driving circuit 700 is an operational amplifier circuit including a first-stage amplifier circuit 702 and a second-stage amplifier circuit 704. The first-stage amplifier circuit 702 includes a first input end receiving an input signal Vpass_ref, a second input end receiving a feedback signal fb, and a first output end providing a driving signal ndrv. The second-stage amplifier circuit 704 includes a third input end connecting the first output end to receive the driving signal ndrv, a second output end providing an output signal VPASS, and a third output end providing the feedback signal fb. In some implementations, the second-stage amplifier circuit 704 further includes a pull-up subcircuit and a pull-down subcircuit.

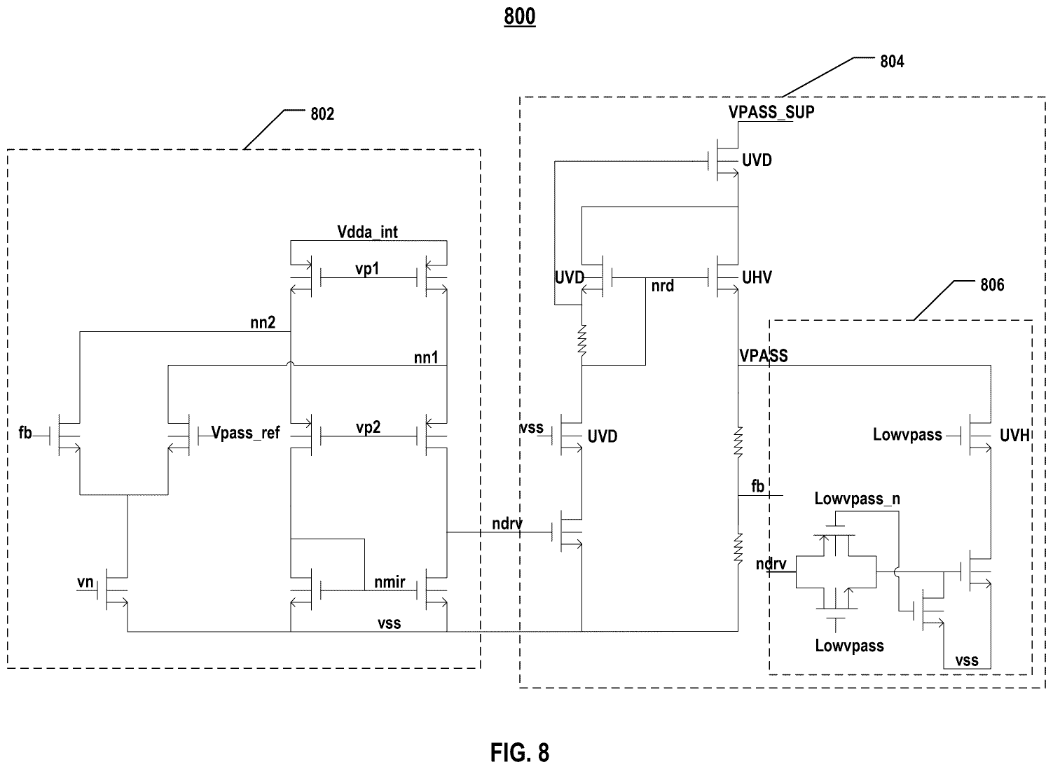

FIG. 8 illustrates a schematic diagram of an exemplary driving circuit 800, according to some implementations of the present disclosure. The driving circuit 800 includes a first-stage amplifier circuit 802 and a second-stage amplifier circuit 804. In some implementations, the first-stage amplifier circuit 802 is operated in a low-voltage range and the second-stage amplifier circuit 804 is operated in a high-voltage range. In some implementations, the first-stage amplifier circuit 802 is operated at about 2.2 volts, and the second-stage amplifier circuit 804 is operated at about 12 volts.

In some implementations, the first-stage amplifier circuit 802 is a folded cascade amplifier. As shown in FIG. 8, the first-stage amplifier circuit 802 is a combination of the common source and the common gate stages. The reference inputs, fb and Vpass_ref, are applied to the common source amplifier, the difference between Vpass_ref and feedback signal fb is amplified, and the output, ndrv, is fed to the common gate stage.

In some implementations, the second-stage amplifier circuit 804 uses a common source input plus a primary source follower output to convert the signal in the low-voltage domain to the high-voltage domain, and through the pull-up structure, an output of about 3 volts to 10 volts can be achieved. In some implementations, the second-stage amplifier circuit 804 includes an indication signal Lowpass to indicate the use of either the pull-up structure or the pull-down structure 806. Since the VPSS_SUP (e.g., about 12 volts) is provided to the second-stage amplifier circuit 804, when the output is pulled up, the output voltage of VPASS can be about 10 volts. When the output voltage of VPASS needs to be pulled down to low (e.g., about 1 volt to 2 volts), the indication signal Lowpass is set to 1, and the inversed indication signal Lowpass_n is set to 0.

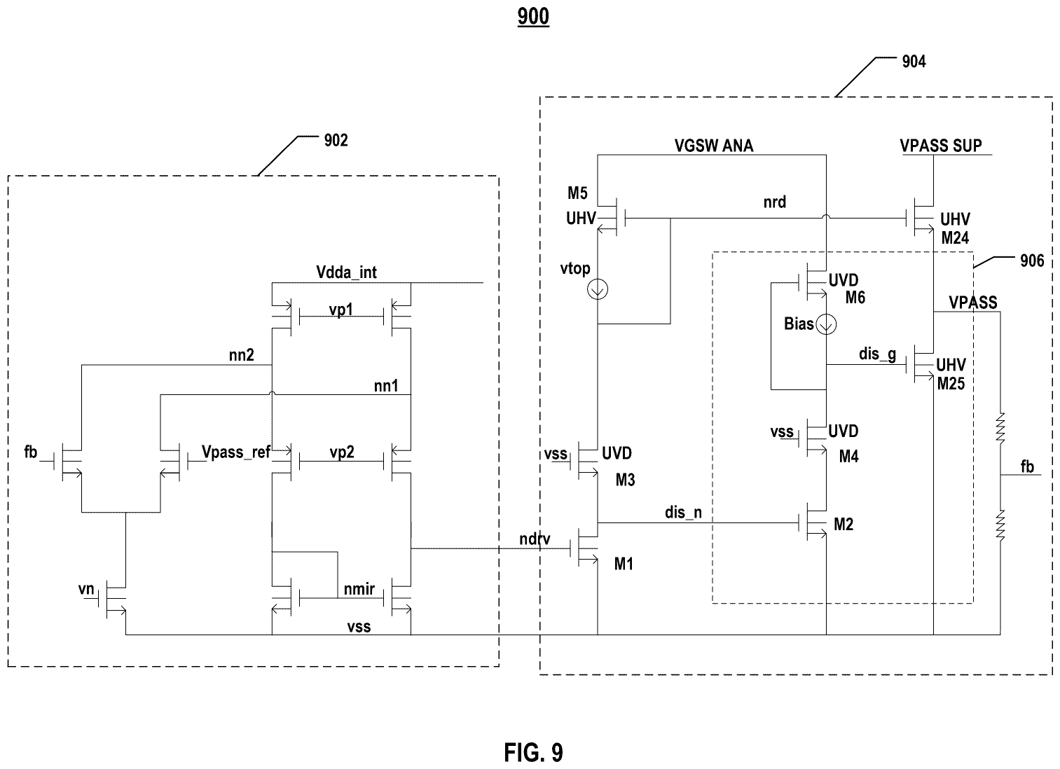

FIG. 9 illustrates a schematic diagram of an exemplary driving circuit 900, according to some implementations of the present disclosure. In some implementations, the driving circuit 900 is an operational amplifier circuit including a first-stage amplifier circuit 902 and a second-stage amplifier circuit 904. The first-stage amplifier circuit 902 includes a first input end receiving an input signal Vpass_ref, a second input end receiving a feedback signal fb, and a first output end providing a driving signal ndrv. In some implementations, the first-stage amplifier circuit 902 includes a first voltage source Vdda_int having a first voltage level. The second-stage amplifier circuit 904 includes a third input end connecting the first output end to receive the driving signal ndrv, a second output end providing an output signal VPASS, and a third output end providing the feedback signal fb. In some implementations, the second-stage amplifier circuit 904 further includes a pull-up subcircuit and a pull-down subcircuit 906. It is noted that, in FIG. 9, the area in the second-stage amplifier circuit 904 other than the marked pull-down subcircuit 906 is the pull-up subcircuit.

The pull-up subcircuit includes a fourth input end and a fourth output end, and the pull-down subcircuit includes a fifth input end and a fifth output end. The fourth input end and the fifth input end connect to the third input end receiving the driving signal ndrv, and the fourth output end and the fifth output end connect to the second output end providing the output signal VPASS.

As shown in FIG. 9, the second-stage amplifier circuit 904 includes a second voltage source VGSW_ANA having a second voltage level different from the first voltage level, and a third voltage source VPASS_SUP having a third voltage level different from the first voltage level and the second voltage level. In some implementations, the second voltage source VGSW_ANA has the second voltage level between 13 volts and 17 volts. In some implementations, the second voltage source VGSW_ANA has the second voltage level of 15 volts. In some implementations, the third voltage source VPASS_SUP has the third voltage level between 10 volts and 14 volts. In some implementations, the third voltage source VPASS_SUP has the third voltage level of 12 volts. In some implementations, the first-stage amplifier circuit 902 and the second-stage amplifier circuit 904 further include a ground reference voltage source VSS.

In some implementations, the first-stage amplifier circuit 902 includes a differential amplifier comparing the input signal Vpass_ref and the feedback signal fb and generating the driving signal ndrv according to a comparison result of the differential amplifier. Then, the second-stage amplifier circuit 904 pulls up or pulls down the output voltage level of the output signal VPASS according to the comparison result of the differential amplifier. In some implementations, the pull-up subcircuit pulls up the output voltage level of the output signal VPASS when the first input voltage level of the input signal Vpass_ref is higher than the feedback voltage level of the feedback signal fb, and the pull-down subcircuit 906 pulls down the output voltage level of the output signal VPASS when the first input voltage level of the input signal Vpass_ref is lower than the feedback voltage level of the feedback signal fb.

As shown in FIG. 9, the pull-up subcircuit includes a first transistor M1 comprising a first end, e.g., the gate, receiving the driving signal ndrv, a second end connecting the ground reference voltage source, e.g., VSS, and a third end connecting a second transistor M5. The second transistor M5 includes a fourth end, e.g., the gate, connecting the third end of the first transistor M1, a fifth end, connecting the third end of the first transistor M1, and a sixth end connecting the second voltage source VGSW_ANA. A third transistor M24 includes a seventh end, e.g., the gate, connecting the fourth end, e.g., the gate, of the second transistor M5, an eighth end connecting the output end VPASS, and a ninth end connecting the third voltage source VPASS_SUP.

In some implementations, the pull-up subcircuit further includes a first high-voltage transistor M3 disposed between the first transistor M1 and the second transistor M5 for protecting the first transistor M1. In some implementations, the first high-voltage transistor M3 has a negative threshold voltage. In some implementations, the pull-up subcircuit further includes a first current source disposed between the first high-voltage transistor M3 and the second transistor M5.

As shown in FIG. 9, the pull-down subcircuit 906 includes a fourth transistor M2 comprising a tenth end connecting the third end of the first transistor M1, an eleventh end connecting the ground reference voltage source VSS, and a twelfth end connecting the second voltage source VGSW_ANA. A fifth transistor M25 includes a thirteenth end connecting the second voltage source VGSW_ANA, a fourteenth end connecting the ground reference voltage source VSS, and a fifteenth end connecting the output end VPASS.

In some implementations, the fifteenth end of the fifth transistor M25 is connected to the third voltage source VPASS_SUP through the third transistor M24. In some implementations, the pull-down subcircuit 906 further includes a second high-voltage transistor M4 disposed between the fourth transistor M2 and the second voltage source VGSW_ANA.

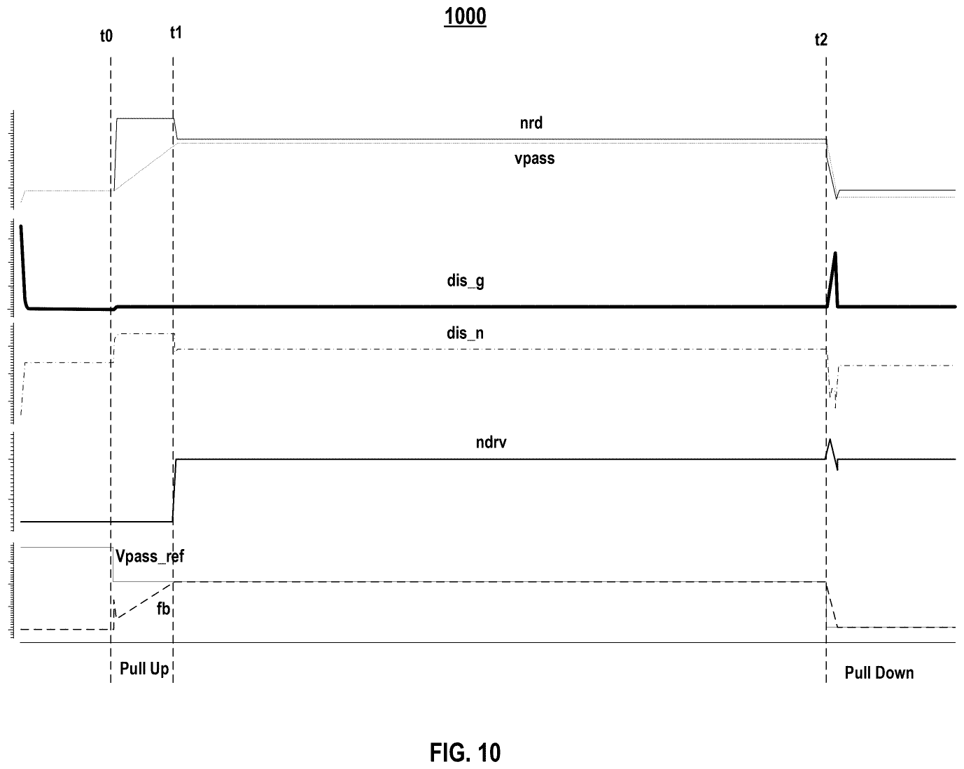

FIG. 10 illustrates a timing diagram showing the operation of the driving circuit 900, according to some implementations of the present disclosure. As shown in FIG. 10, in the pull-up period t0, the voltage level of the input signal Vpass_ref is higher than the feedback voltage level of the feedback signal fb, and the first-stage amplifier circuit 902 outputs a comparison result as low driving signal ndrv.

In the meantime, the voltage nrd is pulled up through self-bias until becoming higher than the target output voltage VPASS. In some implementations, the voltage nrd is pulled up to VPASS+Vth. The voltage dis_n is close to 0.8 v. The output current of the fourth transistor M2 M2 is greater than the bias current on the path, so that the voltage dis_g is pulled down to zero and the fifth transistor M25 is closed. Hence, the pull-down subcircuit 906 is closed.

In the stable period t1, the voltage level of the input signal Vpass_ref is close to the feedback voltage level of the feedback signal fb, and the first-stage amplifier circuit 902 outputs a comparison result as high driving signal ndrv for the normal operating point of the circuit. The size of the transistors in the circuit is preset in the design to ensure that the current of the fourth transistor M2 is greater than the bias current, and the pull-down dis_g will be pulled to VSS to turn off the fifth transistor M25. In this structure, the pull-up loop and the pull-down loop work in a time-sharing manner, and the loop will eventually stabilize at the pull-up loop.

In the pull-down period t2, the voltage level of the input signal Vpass_ref is lower than the feedback voltage level of the feedback signal fb, and the first-stage amplifier circuit 902 outputs a further higher driving signal ndrv. Then, both the voltage dis_n and the voltage nrd are pulled down. When the voltage nrd is pulled to a threshold voltage (Vth) lower than the target output voltage VPASS, the pull-up transistor, the third transistor M24, is turned off. The voltage dis_n is pulled down until the output current of the fourth transistor M2 is lower than the bias current on the path; then, the voltage dis_g will slowly rise, and the pull-down loop works.

By using the driving circuit in the present disclosure, the indicator signal for selecting the pull-up and pull-down paths is not required. Therefore, the circuit area and the elements in the memory device can be effectively reduced. In addition, two voltage sources, VGSW_ANA and VPASS_SUP, are provided to the second-stage amplifier circuit for driving the pull-up and pull-down circuits, and the two voltage sources are provided by the original existing voltage sources in the voltage generator; therefore, no extra circuit is needed.

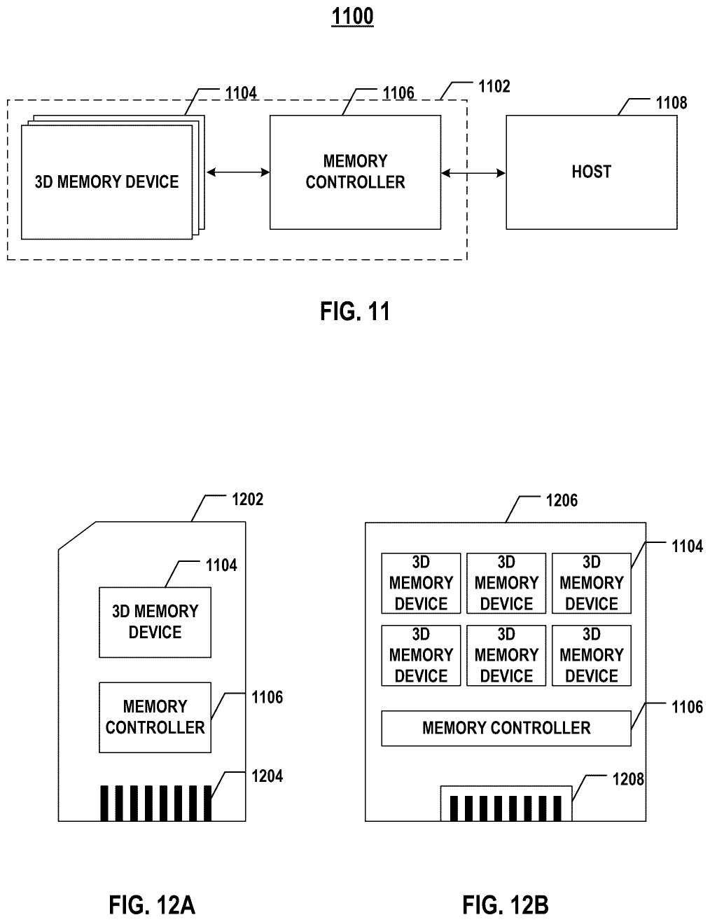

FIG. 11 illustrates a block diagram of a system 1100 having a memory device, according to some aspects of the present disclosure. System 1100 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 11, system 1100 can include a host 1108 and a memory system 1102 having one or more memory devices 1104 and a memory controller 1106. Host 1108 can be a processor of an electronic device, such as a central processing unit (CPU), or a system-on-chip (SoC), such as an application processor (AP). Host 1108 can be configured to send or receive the data to or from memory devices 1104.

Memory controller 1106 is coupled to memory device 1104 and host 1108 and is configured to control memory device 1104, according to some implementations. Memory controller 1106 can manage the data stored in memory device 1104 and communicate with host 1108. In some implementations, memory controller 1106 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 1106 is designed for operating in a high duty-cycle environment SSDs or embedded multi-media-cards (eMMCs) used as data storage for mobile devices, such as smartphones, tablets, laptop computers, etc., and enterprise storage arrays. Memory controller 1106 can be configured to control operations of memory device 1104, such as read, erase, and program operations. In some implementations, memory controller 1106 is configured to control the array of memory cells through the first peripheral circuit and the second peripheral circuit. Memory controller 1106 can also be configured to manage various functions with respect to the data stored or to be stored in memory device 1104 including, but not limited to bad-block management, garbage collection, logical-to-physical address conversion, wear leveling, etc. In some implementations, memory controller 1106 is further configured to process error correction codes (ECCs) with respect to the data read from or written to memory device 1104. Any other suitable functions may be performed by memory controller 1106 as well, for example, formatting memory device 1104. Memory controller 1106 can communicate with an external device (e.g., host 1108) according to a particular communication protocol. For example, memory controller 1106 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 1106 and one or more memory devices 1104 can be integrated into various types of storage devices, for example, be included in the same package, such as a universal Flash storage (UFS) package or an eMMC package. That is, memory system 1102 can be implemented and packaged into different types of end electronic products. In one example as shown in FIG. 12A, memory controller 1106 and a single memory device 1104 may be integrated into a memory card 1202. Memory card 1202 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 1202 can further include a memory card connector 1204 coupling memory card 1202 with a host (e.g., host 1108 in FIG. 11). In another example as shown in FIG. 12B, memory controller 1106 and multiple memory devices 1104 may be integrated into an SSD 1206. SSD 1206 can further include an SSD connector 1208 coupling SSD 1206 with a host (e.g., host 1108 in FIG. 11). In some implementations, the storage capacity and/or the operation speed of SSD 1206 is greater than those of memory card 1202.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents.

What is claimed is:

1. A driving circuit, comprising:
a first-stage amplifier circuit comprising a first input end receiving an input signal, a second input end receiving a feedback signal, and a first output end providing a driving signal, wherein the first-stage amplifier circuit comprises a first voltage source having a first voltage level; and
a second-stage amplifier circuit comprising a third input end connecting the first output end to receive the driving signal, a second output end providing an output signal, and a third output end providing the feedback signal, wherein the second-stage amplifier circuit comprises:
a pull-up subcircuit comprising a fourth input end and a fourth output end; and
a pull-down subcircuit comprising a fifth input end and a fifth output end, wherein the fourth input end and the fifth input end connect to the third input end, and the fourth output end and the fifth output end connect to the second output end.

2. The driving circuit of claim 1, wherein the second-stage amplifier circuit further comprises:
a second voltage source having a second voltage level different from the first voltage level; and
a third voltage source having a third voltage level different from the first voltage level and the second voltage level.

3. The driving circuit of claim 2, wherein the pull-up subcircuit pulls up an output voltage level of the output signal when a first input voltage level of the input signal is higher than a feedback voltage level of the feedback signal, and the pull-down subcircuit pulls down the output voltage level of the output signal when the first input voltage level of the input signal is lower than the feedback voltage level of the feedback signal.

4. The driving circuit of claim 3, wherein the first-stage amplifier circuit and the second-stage amplifier circuit further comprise a ground reference voltage source.

5. The driving circuit of claim 4, wherein the first-stage amplifier circuit comprises a differential amplifier comparing the input signal and the feedback signal and generating the driving signal according to a comparison result of the differential amplifier.

6. The driving circuit of claim 5, wherein the second-stage amplifier circuit pulls up or pulls down the output voltage level of the output signal according to the comparison result of the differential amplifier.

7. The driving circuit of claim 2, wherein the second voltage level of the second voltage source is greater than the third voltage level of the third voltage source.

8. The driving circuit of claim 7, wherein the second voltage level is between 13 volts and 17 volts.

9. The driving circuit of claim 7, wherein the third voltage level is between 10 volts and 14 volts.

10. The driving circuit of claim 5, wherein the pull-up subcircuit comprises:
a first transistor comprising a first end receiving the driving signal, a second end connecting the ground reference voltage source, and a third end;
a second transistor comprising a fourth end connecting the third end of the first transistor, a fifth end connecting the third end of the first transistor, and a sixth end connecting the second voltage source; and
a third transistor comprising a seventh end connecting the fourth end of the second transistor, an eighth end connecting the second output end, and a ninth end connecting the third voltage source.

11. The driving circuit of claim 10, wherein the pull-up subcircuit further comprises:
a first high-voltage transistor disposed between the first transistor and the second transistor.

12. The driving circuit of claim 11, wherein the pull-up subcircuit further comprises:
a first current source disposed between the first high-voltage transistor and the second transistor.

13. The driving circuit of claim 10, wherein the third transistor is disposed between the third voltage source and the second output end.

14. The driving circuit of claim 10, wherein the pull-down subcircuit comprises:
a fourth transistor comprising a tenth end connecting the third end of the first transistor, an eleventh end connecting the ground reference voltage source, and a twelfth end connecting the second voltage source; and
a fifth transistor comprising a thirteenth end connecting the second voltage source, a fourteenth end connecting the ground reference voltage source, and a fifteenth end connecting the second output end.

15. The driving circuit of claim 14, wherein the pull-down subcircuit further comprises:
a second high-voltage transistor disposed between the fourth transistor and the second voltage source.

16. A memory device, comprising:
a memory cell array comprising a plurality of memory cells and a plurality of word lines coupled to the plurality of memory cells; and
a peripheral circuit, coupled to the memory cell array, configured to control the memory cell array, the peripheral circuit comprising a driving circuit;
wherein the driving circuit, comprising:
a first-stage amplifier circuit comprising a first input end receiving an input signal, a second input end receiving a feedback signal, and a first output end providing a driving signal, wherein the first-stage amplifier circuit comprises a first voltage source having a first voltage level; and
a second-stage amplifier circuit comprising a third input end connecting the first output end to receive the driving signal, a second output end providing an output signal, and a third output end providing the feedback signal, wherein the second-stage amplifier circuit comprises:
a pull-up subcircuit comprising a fourth input end and a fourth output end; and
a pull-down subcircuit comprising a fifth input end and a fifth output end, wherein the fourth input end and the fifth input end connect to the third input end, and the fourth output end and the fifth output end connect to the second output end.

17. The memory device of claim 16, wherein the second-stage amplifier circuit further comprises:
a second voltage source having a second voltage level different from the first voltage level; and
a third voltage source having a third voltage level different from the first voltage level and the second voltage level.

18. The memory device of claim 17, wherein the pull-up subcircuit pulls up an output voltage level of the output signal when a first input voltage level of the input signal is higher than a feedback voltage level of the feedback signal, and the pull-down subcircuit pulls down the output voltage level of the output signal when the first input voltage level of the input signal is lower than the feedback voltage level of the feedback signal.

19. The memory device of claim 17, wherein the peripheral circuit comprises a voltage generator and a word line driver, the voltage generator provides the second voltage source and the output signal to the word line driver.

20. A system, comprising:
a memory device, comprising:
a memory cell array comprising a plurality of memory cells and a plurality of word lines coupled to the plurality of memory cells; and
a peripheral circuit, coupled to the memory cell array, configured to control the memory cell array, the peripheral circuit comprising a driving circuit;
wherein the driving circuit, comprising:
a first-stage amplifier circuit comprising a first input end receiving an input signal, a second input end receiving a feedback signal, and a first output end providing a driving signal, wherein the first-stage amplifier circuit comprises a first voltage source having a first voltage level; and
a second-stage amplifier circuit comprising a third input end connecting the first output end to receive the driving signal, a second output end providing an output signal, and a third output end providing the feedback signal, wherein the second-stage amplifier circuit comprises:
a pull-up subcircuit comprising a fourth input end and a fourth output end; and
a pull-down subcircuit comprising a fifth input end and a fifth output end, wherein the fourth input end and the fifth input end connect to the third input end, and the fourth output end and the fifth output end connect to the second output end.
a memory controller coupled to the memory device and configured to control operations of the peripheral circuit.
